(19) United States
(12) Patent Application Publication
(10) Pub. No.: US 2023/0051389 A1
(43) Pub. Date: Feb. 16, 2023

(54) SEMICONDUCTOR DEVICE AND METHOD OF MANUFACTURING SEMICONDUCTOR DEVICE

(71) Applicant: FUJI ELECTRIC CO., LTD., Kawasaki-shi (JP)

(72) Inventor: Naoki TAKIZAWA, Matsumoto-city (JP)

(73) Assignee: FUJI ELECTRIC CO., LTD., Kawasaki-shi (JP)

(21) Appl. No.: 17/977,982

(22) Filed: Oct. 31, 2022

Related U.S. Application Data
(63) Continuation of application No. PCT/JP2021/034829, filed on Sep. 22, 2021.

(30) Foreign Application Priority Data
Nov. 16, 2020 (JP) 2020-190052

(51) Int. Cl. H01L 23/492; H01L 25/07; H01L 21/48; H01L 23/367; H01L 23/498; H01L 23/373

(52) U.S. Cl. CPC H01L 23/4924; H01L 21/4875; H01L 21/4882; H01L 23/367; H01L 23/3736; H01L 23/49833; H01L 25/072; H01L 24/32; H01L 2224/32225; H01L 2924/3511; H01L 2924/13055; H01L 2924/13091; H01L 2924/35121

(57) ABSTRACT

A metal base plate is rectangular in plan view, has a joining region set on a front surface, and has a center line, which is parallel to a pair of short sides that face each other, set in a middle interposed between the pair of short sides. A ceramic circuit board includes a ceramic board that is rectangular in plan view, a circuit pattern that is formed on a front surface of the ceramic board and has a semiconductor chip joined thereto, and a metal plate that is formed on a rear surface of the ceramic board and is joined to the joining region by solder. Here, the solder contains voids and is provided with a stress relieving region at one edge portion that is away from the center line. A density of voids included in the stress relieving region is higher than other regions of the solder.

### CROSS-REFERENCE TO RELATED APPLICATION

This application is a continuation application of International Application PCT/JP2021/034829 filed on Sep. 22, 2021 which designated the U.S., which claims priority to Japanese Patent Application No. 2020-190052, filed on Nov. 16, 2020, the entire contents of which are incorporated herein by reference.

### BACKGROUND OF THE INVENTION

### 1. Field of the Invention

The embodiments discussed herein relate to a semiconductor device and a method of manufacturing a semiconductor device.

### 2. Background of the Related Art

A semiconductor device includes a plurality of ceramic circuit boards, semiconductor chips mounted on the respective ceramic circuit boards, and a metal base plate that has the plurality of ceramic circuit boards joined to its front surface. The ceramic circuit boards each include a ceramic board, a metal plate provided on a rear surface of the ceramic board, and a circuit pattern provided on a front surface of the ceramic board. The semiconductor chips are provided on the circuit patterns of the ceramic circuit boards. The semiconductor chips include power devices. As examples, power devices may be insulated gate bipolar transistors (IGBTs), and power metal oxide semiconductor field effect transistors (MOSFETs). The plurality of ceramic circuit boards on which the semiconductor chips have been provided are provided via solder on the front surface of the metal base plate. In a semiconductor device, heat from semiconductor chips that have heated up is transmitted from the ceramic circuit boards to the metal base plate and caused to dissipate. An example way of improving the dissipation of heat by a semiconductor device is to make the solder between the ceramic circuit boards and the metal base plate thinner.

Japanese Laid-open Patent Publication No. 2015-170826

However, in a semiconductor device where the solder is made too thin, there is a tendency for excessive stress to act upon the ceramic circuit boards and/or the solder due to factors such as a difference in thermal expansion between the metal base plate and the ceramic circuit boards. This means that there is the risk of the ceramic circuit boards and/or the solder peeling and/or cracking, which would damage the semiconductor device.

### SUMMARY OF THE INVENTION

According to an aspect, there is provided a semiconductor device, including: a first semiconductor chip; a metal base plate which is rectangular in a plan view of the semiconductor device, has a joining region disposed on a front surface thereof, and has a first center line that is parallel to a pair of first sides which face each other and in a middle so as to be interposed between the pair of first sides; a first joining member; and a first insulated circuit board including a first insulated board that is rectangular in the plan view, a first circuit pattern that is formed on a front surface of the first insulated board and has the first semiconductor chip joined thereto, and a first metal plate that is formed on a rear surface of the first insulated board and joined to the joining region by the first joining member, wherein the first joining member: joins the metal base plate and the first metal plate, and has a fillet formed so as to flare outwardly from an outer peripheral end portion of the first metal plate, and part of a first edge portion of the first joining member, which is located away from the first center line, is provided with a first stress relieving region, the first joining member having plural regions including the first stress relieving region, that contain voids, a density of the voids contained in the first stress relieving region being higher than densities of the voids contained in others of the plural regions of the first joining member.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is a plan view of a semiconductor device according to the present embodiments;

FIG. 2 is a plan view of solder in the semiconductor device according to the present embodiments;

FIG. 3 is a cross-sectional view of the semiconductor device according to the present embodiments;

FIG. 4 is a flowchart of a method of manufacturing a semiconductor device according to the present embodiments;

FIG. 5 depicts a mounting process included in the method of manufacturing a semiconductor device according to the present embodiments;

FIG. 6 is a first diagram depicting a heating process included in the method of manufacturing a semiconductor device according to the present embodiments;

FIG. 7 is a second diagram depicting a heating process included in the method of manufacturing a semiconductor device according to the present embodiments;

FIG. 8 depicts a cooling process included in the method of manufacturing a semiconductor device according to the present embodiments;

FIGS. 9A to 9C depict solder in the heating process and the cooling process in the method of manufacturing a semiconductor device according to the present embodiments;

FIG. 10 is a first plan view of a semiconductor device that is a comparative example;

FIGS. 11A and 11B are first cross-sectional views of a semiconductor device that are a comparative example;

FIG. 12 is a second plan view of a semiconductor device that is a comparative example;

FIG. 13 is a second cross-sectional view of a semiconductor device that is a comparative example;

FIG. 14 is a third cross-sectional view of a semiconductor device that is a comparative example;

FIGS. 15A and 15B are plan views of semiconductor devices that are a first modification to the present embodiments;

FIG. 16 is a plan view of a semiconductor device that is a second modification to the present embodiments;

FIGS. 17A and 17B are plan views of semiconductor devices that are third and fourth modifications to the present embodiments; and

FIG. 18 is a plan view of a semiconductor device that is a fifth modification to the present embodiments.

### DETAILED DESCRIPTION OF THE INVENTION

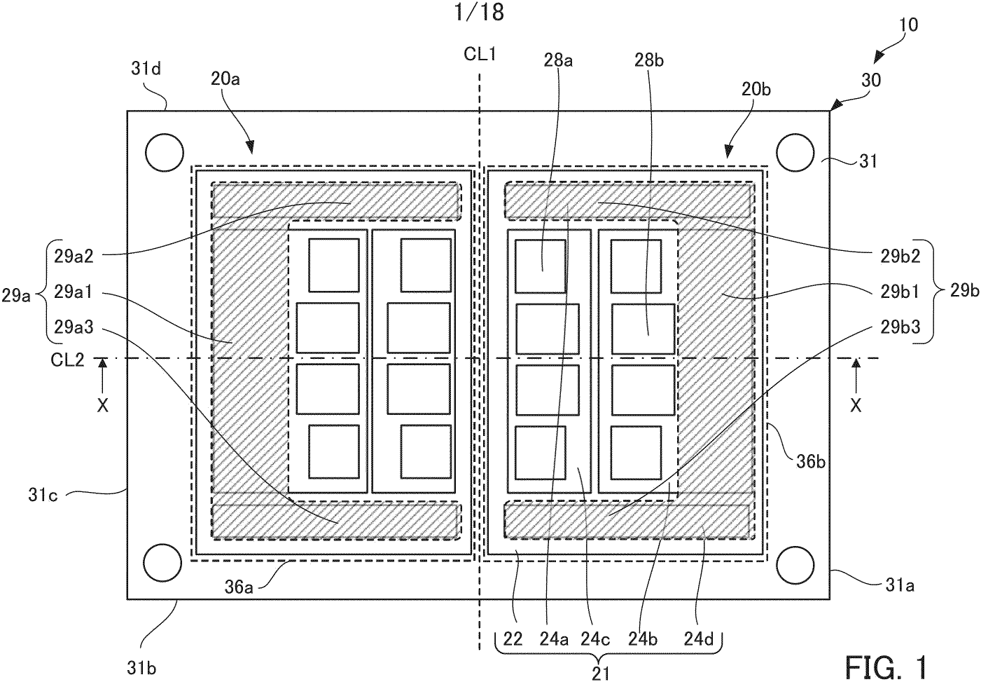

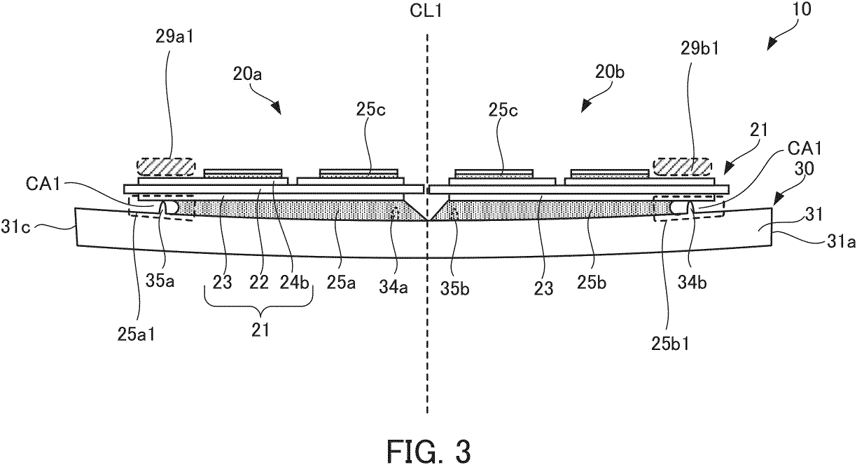

Several embodiments will be described below with reference to the accompanying drawings. Note that in the following description, the expressions “front surface” and “upper surface” refer to a surface facing upward of a semiconductor device 10 depicted in FIG. 1 and FIG. 3. In the same way, the expression “up” refers to the upward direction for the semiconductor device 10 depicted in FIG. 1 and FIG. 3. The expressions “rear surface” and “lower surface” refer to a surface facing downward of the semiconductor device 10 depicted in FIG. 1 and FIG. 3. In the same way, the expression “down” refers to the downward direction for the semiconductor device 10 depicted in FIG. 1 and FIG. 3. These expressions are used as needed to refer to the same directions in the other drawings. The expressions “front surface”, “upper surface”, “up”, “rear surface”, “lower surface”, “down”, and “side surface” are merely convenient expressions used to specify relative positional relationships, and are not intended to limit the technical scope of the present embodiments. As one example, “up” and “down” do not necessarily mean directions that are perpendicular to the ground. That is, the “up” and “down” directions are not limited to the direction of gravity. Additionally, in the following description, the expression “main component” refers to a component that composes 80% or higher by volume out of all the components.

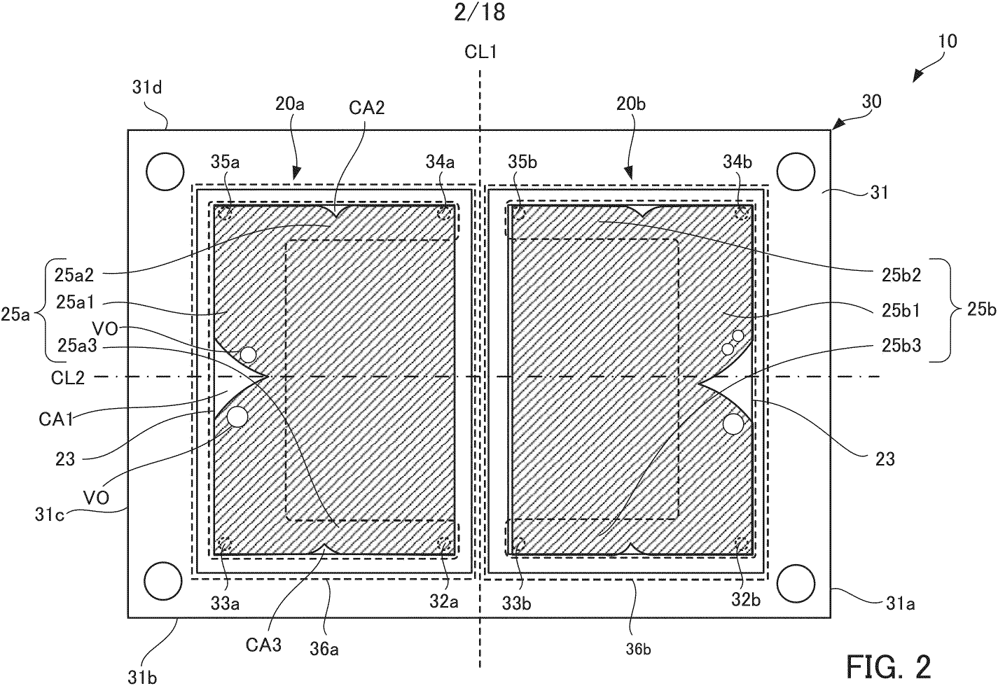

A semiconductor device according to the present embodiments will now be described with reference to FIGS. 1 to 3. FIG. 1 is a plan view of the semiconductor device according to the present embodiments, FIG. 2 is a plan view of solder in the semiconductor device according to the present embodiments, and FIG. 3 is a cross-sectional view of the semiconductor device according to the present embodiments. Note that a center line CL1 depicted in FIGS. 1 and 2 is parallel to a pair of facing short sides 31a and 31c of a metal base plate 30, and passes through the middle between the pair of short sides 31a and 31c. A center line CL2 is parallel to a pair of facing long sides 31b and 31d of the metal base plate 30, and passes through the middle between the pair of long sides 31b and 31d. That is, an intersection of the center lines CL1 and CL2 is a center point of the semiconductor device 10 in plan view. Note that the center line CL1 is indicated using a broken line and the center line CL2 is indicated using a dot-dash line. FIG. 2 is a plan view of solder 25a and 25b when semiconductor units 20a and 20b depicted in FIG. 1 have been removed. FIG. 3 is a cross-sectional view taken along a dot-dash line X-X in FIG. 1.

The semiconductor device 10 includes the two semiconductor units 20a and 20b and the metal base plate 30 on which the semiconductor units 20a and 20b are provided via the solder 25a and 25b. The semiconductor units 20a and 20b are disposed along the long sides 31b and 31d of the metal base plate 30. That is, the center line CL2 crosses the centers of the semiconductor units 20a and 20b. In addition, the semiconductor units 20a and 20b are disposed on the metal base plate 30 so as to have line symmetry with respect to the center line CL1. The semiconductor units 20a and 20b disposed in this way are disposed at right angles to and in parallel with the metal base plate 30. That is, the respective sides of the semiconductor units 20a and 20b are parallel with the short sides 31a and 31c and the long sides 31b and 31d of the metal base plate 30. Note that when not making any particular distinction between the semiconductor units 20a and 20b, the following description will refer to the “semiconductor units 20”.

The semiconductor units 20a and 20b each include a ceramic circuit board 21 and semiconductor chips 28a and 28b disposed via solder (not illustrated) on the ceramic circuit board 21. That is, the semiconductor units 20a and 20b are both formed of similar components. The ceramic circuit boards 21 are rectangular in plan view. The ceramic circuit boards 21 each include a ceramic board 22, a metal plate 23 provided on a rear surface of the ceramic board 22, and circuit patterns 24a to 24d provided on a front surface of the ceramic board 22. The semiconductor chips 28a and 28b are mechanically and electrically connected by solder to the circuit patterns 24a to 24d.

The ceramic boards 22 are rectangular in plan view. The corners of the ceramic boards 22 may also be chamfered. As examples, the corners may be chamfered into a rounded or beveled shape. The ceramic boards 22 are made of a ceramic with favorable thermal conductivity. As examples, the ceramic is made of aluminum oxide, aluminum nitride, or a material that contains silicon nitride as a main component. The thickness of the ceramic boards 22 is at least 0.5 mm but not greater than 2.0 mm.

The metal plates 23 are rectangular in plan view. The corners of the metal plate 23 may also be chamfered. As examples, the corners may be chamfered into a rounded or beveled shape. The metal plates 23 are smaller in size than the ceramic boards 22 and are formed on the entire surfaces of the ceramic boards 22 except for edge portions of the ceramic boards 22. The metal plates 23 are made of a metal that has favorable thermal conductivity as a main component. As examples, the metal is copper, aluminum, or an alloy including at least one of copper and aluminum. The thickness of the metal plates 23 is at least 0.1 mm but not greater than 2.0 mm. To improve corrosion resistance, the metal plates 23 may be subjected to a plating treatment. When doing so, as examples, the plating material in used is nickel, nickel-phosphorus alloy, or nickel-boron alloy.

The circuit patterns 24a to 24d are formed over the entire surfaces of the ceramic boards 22, except for the edge portions of the ceramic boards 22. It is preferable for end portions of the circuit patterns 24a to 24d at the outer periphery of the ceramic boards 22 to be positioned above end portions of the metal plates 23 at the outer periphery of the ceramic boards 22. The circuit patterns 24a and 24d, to which the semiconductor chips 28a and 28b are not joined, are formed on the ceramic board 22 so as to be close to the long sides 31d and 31b of the metal base plate 30. The circuit patterns 24b and 24c, to which the semiconductor chips 28a and 28b are joined, are formed on the ceramic board 22 between the circuit patterns 24a and 24d. The circuit patterns 24c are formed close to the center line CL1, and the circuit patterns 24b are formed far from the center line CL1, are adjacent to the circuit patterns 24c, and are formed so as to extend to the short sides 31a and 31c of the metal base plate 30.

In a hypothetical configuration where the circuit patterns 24b were not formed in a region that is positioned above first stress relieving regions 25a1 and 25b1, described later, in plan view, the stress between the ceramic circuit boards 21 and the metal plates 23 on the rear surfaces of the ceramic boards 22 would become unbalanced. This would result in the risk of the ceramic boards 22 becoming damaged, such as excessive warping and cracking. Note that in the present embodiments, a configuration is illustrated where the circuit patterns 24b extend as far as regions that are positioned above the first stress relieving regions 25a1 and 25b1. That is, the circuit patterns 24b each include an unmounted region, which is a region that is positioned above the first stress relieving regions 25a1 and 25b1 but where the semiconductor chips 28a and 28b are not mounted. The present embodiments are not limited to this configuration, and it is also possible to form the circuit patterns 24b in regions that are not positioned above the first stress relieving regions 25a1 and 25b1 and to form other circuit patterns in regions that are positioned above the first stress relieving regions 25a1 and 25b1. As one example, it is possible to extend the circuit patterns 24a and 24d to regions that are positioned above the first stress relieving regions 25a1 and 25b1.

The thickness of the circuit patterns 24a to 24d is at least 0.5 mm but not greater than 1.5 mm. The circuit patterns 24a to 24d are made of a metal with superior electrical conductivity. Examples of such metals include copper, aluminum, and an alloy including at least one of copper and aluminum. To improve corrosion resistance, surfaces of the circuit patterns 24a to 24d may be subjected to a plating treatment. When doing so, as examples, the plating material in use is nickel, nickel-phosphorus alloy, or nickel-boron alloy. The circuit patterns 24a to 24d are obtained on the ceramic boards 22 by forming a metal plate on the front surfaces of the ceramic boards 22 and performing a process such as etching on the metal plate. Alternatively, the circuit patterns 24a to 24d that have been cut out from a metal plate in advance may be crimped to the front surface of the ceramic boards 22. Note that the circuit patterns 24a to 24d are mere examples. Appropriate numbers, shapes, sizes, and the like of the circuit patterns may be selected as needed. As examples, direct copper bonding (DCB) substrates or active metal brazed (AMB) substrates may be used as the ceramic circuit boards 21.

Also, as depicted in FIG. 1, low-heat-dissipation regions 29a and 29b are set along three sides in plan view on the front surfaces of the ceramic circuit boards 21 of the semiconductor units 20a and 20b. That is, the low-heat-dissipation regions 29a and 29b include short side parts 29a1 and 29b1 and long side parts 29a2, 29a3, 29b2 and 29b3. The short side parts 29a1 and 29b1 are set on the front surfaces of the ceramic circuit boards 21 on the short side 31c and 31a sides that are far from the center line CL1 of the metal base plate 30 (or “heat dissipating plate 31”). The long side parts 29a2, 29a3, 29b2, and 29b3 are set on the front surfaces of the ceramic circuit boards 21 on the long side 31d and 31b sides on both sides of the center line CL2 of the metal base plate 30 (or “heat dissipating plate 31”). Also, as depicted in FIG. 2, in the solder 25a and 25b of the semiconductor units 20a and 20b, stress relieving regions 25a1 to 25a3 and 25b1 to 25b3 are set at positions that are positioned above the low-heat-dissipation regions 29a and 29b in plan view. Note that the low-heat-dissipation regions 29a and 29b and the stress relieving regions 25a1 to 25a3 and 25b1 to 25b3 will be described later in this specification.

The semiconductor chips 28a include a switching element. As examples, the switching element is an IGBT or a power MOSFET. When a semiconductor chip 28a is an IGBT, on the rear surface, the collector electrode is provided as a main electrode, and on the front surface, the gate electrode is provided as a control electrode and the emitter electrode is provided as a main electrode. When a semiconductor chip 28a is a power MOSFET, on the rear surface, a drain electrode is provided as a main electrode, and on the front surface, a gate electrode is provided as a control electrode and a source electrode is provided as a main electrode. The rear surfaces of the semiconductor chips 28a described above are joined to the circuit patterns 24c by solder (not illustrated). Wiring members are electrically and mechanically connected as appropriate to the main electrode and the gate electrode on the front surfaces of the semiconductor chips 28a. As examples, the wiring members are bonding wires, lead frames, or pin-shaped or ribbon-shaped members.

The semiconductor chips 28b include diodes. As examples, the diodes are free wheeling diodes (FWD), such as a Schottky Barrier diode (SBD) or a P-intrinsic-N (PiN) diode. The semiconductor chips 28b of this type each have an output electrode (or “cathode electrode”) as a main electrode on the rear surface and an input electrode (or “anode electrode”) as a main electrode on the front surface. The rear surfaces of the semiconductor chips 28b described above are joined to the circuit patterns 24b by solder (not illustrated). Note that the semiconductor chips 28b are joined to a region of the circuit patterns 24b aside from regions that are positioned above the low-heat-dissipation regions 29a and 29b. Wiring members are also electrically and mechanically connected as appropriate to the main electrodes on the front surfaces of the semiconductor chips 28b. As examples, the wiring members are bonding wires, lead frames, or pin-shaped or ribbon-shaped members.

Reverse-conducting (RC)-IGBT with the functions of both an IGBT and an FWD may also be used in place of the semiconductor chips 28a and 28b. Note also that FIGS. 1 and 3 merely illustrate a case where two sets of semiconductor chips 28a and 28b are provided. The present embodiments are not limited to two sets, and the number of sets may be set according to the specification and the like of the semiconductor device 10. Such semiconductor chips are joined to the front surface of the ceramic circuit board 21 at regions aside from the low-heat-dissipation regions 29a and 29b that are positioned above the stress relieving regions 25a1 to 25a3 and 25b1 to 25b3.

Wiring members and electronic components for example may also be mounted depending on the design, specification, and the like of the semiconductor device 10. In such case, the wiring members and electronic components may be mounted in regions of the circuit patterns 24b that are positioned above the low-heat-dissipation regions 29a and 29b. Note that the wiring members may be terminals, lead frames, or wires for example. Example electronic components include resistors, capacitors, and thermistors.

Lead-free solder is used as the solder for joining the semiconductor chips 28a and 28b and the circuit patterns 24b and 24c. Lead-free solder contains at least one out of a plurality of alloys as a main component. As examples, this plurality of alloys includes an alloy made of tin, silver, and copper, an alloy made of tin, zinc, and bismuth, an alloy made of tin and copper, and an alloy made of tin, silver, indium, and bismuth. The solder may additionally contain additives. Example additives include nickel, germanium, cobalt, and silicon. Solder that contains additives has improved wettability, gloss, and bonding strength, which may improve reliability. A sintered metal may be used in place of the solder. The material of the sintered metal has silver or silver alloy as a main component.

The metal base plate 30 is made of a metal with superior thermal conductivity. Examples of such metals include aluminum, iron, silver, copper, and an alloy containing at least one of aluminum, iron, silver, and copper. To improve corrosion resistance, the surface of the metal base plate 30 may be subjected to a plating treatment. When doing so, as examples, the plating material in use is nickel, nickel-phosphorus alloy, or nickel-boron alloy. The metal base plate 30 has a larger coefficient of thermal expansion than the ceramic circuit board 21. The metal base plate 30 may be rectangular in plan view. The corners of the metal base plate 30 may also be chamfered. As examples, the corners may be chamfered into a rounded or beveled shape. The metal base plate 30 described here is provided with a heat dissipating plate 31 and protruding portions 32a to 35a and 32a to 35b formed on a front surface of the heat dissipating plate 31.

The heat dissipating plate 31 is a flat plate-shaped part of the metal base plate 30. As depicted in FIG. 3, when a center portion of a rear surface through which the center line CL1 passes is regarded as the bottom, the heat dissipating plate 31 is warped into a downwardly convex shape. That is, the heat dissipating plate 31 is warped so that the center portion of the heat dissipating plate 31 forms the bottom and the short sides 31a and 31c and the long sides 31b and 31d become positioned above the center portion. As described later, this occurs due to heating performed during the manufacturing process of the semiconductor device 10. The overall average thickness of the heat dissipating plate 31 is at least 1 mm but not greater than 10 mm. Joining regions 36a and 36b are also set on the front surface of the heat dissipating plate 31. The semiconductor units 20a and 20b are disposed in the joining regions 36a and 36b as described later. The metal base plate 30 (heat dissipating plate 31) is warped so that the center portion is downwardly convex. For this reason, the two joining regions 36a and 36b are not set in the center portion of the heat dissipating plate 31, and are instead set so as to have line symmetry on both sides of the center line CL1 of the heat dissipating plate 31. In more detail, in the configuration in FIG. 1, the joining regions 36a and 36b are set on the left and right sides of the center line CL1 that passes through the center portion of the heat dissipating plate 31 and is parallel to the short sides 31a and 31c. Note that as needed, the heat dissipating plate 31 has mounting holes formed at corner portions and the like. The metal base plate 30 is mounted at a predetermined position and a cooler, described later, is also mounted by screwing into the mounting holes.

Also on the metal base plate 30, the protruding portions 32a to 35a and 32b to 35b are integrally formed at corner portions of the joining regions 36a and 36b, respectively, of the heat dissipating plate 31. The joining regions 36a and 36b of the heat dissipating plate 31 may be located at positions that face the semiconductor units 20a and 20b. That is, the joining regions 36a and 36b of the heat dissipating plate 31 may be located at positions facing the rear surfaces of the metal plates 23 of the ceramic circuit boards 21. Accordingly, the protruding portions 32a to 35a and 32b to 35b may be located at positions facing corner portions of the semiconductor units 20a and 20b. Additionally, the protruding portions 32a to 35a and 32b to 35b may be located at positions facing corner portions of the rear surfaces of the metal plate 23 of the ceramic circuit board 21. Note that the heights of the protruding portions 32a to 35a and 32b to 35b are the same. As one example, the height is at least 0.05 mm but not greater than 0.5 mm. As one example, the diameter of the protruding portions 32a to 35a and 32b to 35b is at least 50 µm but not greater than 500 µm. Also, the protruding portions 32a to 35a and 32b to 35b are not limited to being rod-shaped as depicted in FIG. 3. As examples, the protruding portions 32a to 35a and 32b to 35b may be hemispherical, semi-elliptical, or cubic. Alternatively, the protruding portions 32a and 34a may be continuous and have a convex shape along the side of the ceramic circuit board 21. In the same way, the protruding portions 33b and 35b, the protruding portions 33a and 35a, and the protruding portions 32b and 34b may be continuous and have convex shapes along the sides of the ceramic circuit board 21.

A cooler (not illustrated) may be attached to the rear surface of the metal base plate 30 via a heat dissipation sheet or thermal grease. When a cooler is attached, the mounting holes of the metal base plate 30 and the cooler are screwed together. Alternatively, the cooler may be joined via solder, silver brazing, or the like. By doing so, it is possible to improve the dissipation of heat by the metal base plate 30. The cooler used here is made of a metal with superior thermal conductivity. Example metals include aluminum, iron, silver, copper, or an alloy containing at least one of aluminum, iron, silver, and copper. It is also possible to use a heat sink formed of a plurality of fins, a cooling device that uses water cooling, or the like as the cooler. The metal base plate 30 may be integrated with a cooler of this type. To improve corrosion resistance, the surface of the cooler attached to the metal base plate 30 may be subjected to a plating process. Examples of the plating material used when doing so are nickel, nickel-phosphorus alloy, and nickel-boron alloy.

The semiconductor units 20a and 20b are provided via the solder 25a and 25b in the joining regions 36a and 36b of the metal base plate 30. When doing so, as depicted in FIG. 3, the solder 25a and 25b is formed between the front surface of the metal base plate 30 and the rear surfaces of the metal plates 23 of the ceramic circuit boards 21. By doing so, the front surface of the metal base plate 30 and the rear surface of the metal plate 23 of the ceramic circuit board 21 are joined. Note that in FIG. 3, the positions of the protruding portions 34a and 35b are indicated by broken lines. Tip portions of the protruding portions 33a and 35a and the protruding portions 32b and 34b that are far from the center line CL1 of the metal base plate 30 make contact with the rear surfaces of the semiconductor units 20a and 20b. On the other hand, all parts, including the tip portions, of the protruding portions 32a and 34a and the protruding portions 33b and 35b close to the center line CL1 are separated from the rear surface of the semiconductor units 20a and 20b. By doing so, the ceramic circuit boards 21 are kept substantially horizontal. The solder 25a and 25b is also interposed between the ceramic circuit boards 21 and the joining regions 36a and 36b of the metal base plate 30. Accordingly, the thickness of the solder 25a and 25b at positions far from the center line CL1 corresponds to the heights of the protruding portions 33a, 35a, 32b and 34b.

The solder 25a and 25b will now be described in detail. Note that as the solder 25a and 25b, the same solder as the solder for joining the semiconductor chips 28a and 28b and the circuit patterns 24b and 24c (which is indicated as the solder 25c in FIG. 3) is used. Like the solder described earlier, the solder 25a and 25b may contain additives as needed.

The solder 25a and 25b joins the metal base plate 30 and the metal plates 23. The solder 25a and 25b is formed as fillets shaped so as to smoothly flare outward from outer peripheral end portions of the metal plates 23. The solder 25a and 25b is shaped to correspond to the joining regions 36a and 36b of the metal base plate 30, which is warped so as to be downwardly convex, and the metal plates 23, which are flat. That is, the metal plate 23 sides of the solder 25a and 25b are substantially flat, and the metal base plate 30 sides of the solder 25a and 25b are curved in a bow shape. The thickness of the solder 25a and 25b is made sufficiently thin. The thickness of the solder 25a and 25b is thinner at the outside away from the center line CL1 (that is, close to the short sides 31a and 31c of the metal base plate 30) than at positions close to the center line CL1. It is preferable for the thickness of the solder 25a and 25b to be at least 0.20 mm but not greater than 0.60 mm at edge portions close to the center line CL1 and at least 0.05 mm but not greater than 0.45 mm at edge portions far from the center line CL1. As one example, the thickness at an edge portion distant from the center line CL1 is around 0.25 mm, and the thickness at an edge portion close to the center line CL1 is around 0.40 mm. Alternatively, the solder 25a and 25b includes a part that is warped in keeping with the shape of the metal base plate 30. To do so, the solder 25a and 25b may have a part, which is thicker than edge portions close to the center line CL1, extending from the edge portions close to the center line CL1 as far as the edge portions distant from the center line CL1.

As depicted in FIG. 2, the solder 25a and 25b includes the stress relieving regions 25a1 to 25a3 and 25b1 to 25b3, respectively. The stress relieving regions 25a1 to 25a3 and 25b1 to 25b3 are regions where the density of voids (that is, shrinkage cavities CA1 to CA3 and voids VO) included in the solder 25a and 25b is higher than in other regions. The stress relieving regions 25a1 and 25b1 (or “first stress relieving regions”) are included in regions of the solder 25a and 25b of a predetermined width along edge portions that are far from the center line CL1. The stress relieving regions 25a2, 25a3, 25b2, and 25b3 (or “second stress relieving regions”) are respectively included at edge portions of the solder 25a and 25b that are far from the center line CL2. The stress relieving regions 25a1 to 25a3 and 25b1 to 25b3 may be regions from a side of the joining regions 36a and 36b that is far from the center line CL1 or CL2 to a position located inward by at least 5% but not greater than 30% of a length of a side perpendicular to this side.

In addition, the stress relieving regions 25a1 to 25a3 and 25b1 to 25b3 may be regions that correspond to central portions of respective sides of the ceramic circuit boards 21. This is because in the semiconductor device 10, as depicted in FIG. 2, the shrinkage cavities CA1 to CA3 are produced so as to extend inward from the centers of the sides that are far from the center line CL1 or CL2 of the ceramic circuit boards 21. Note that the shrinkage cavity CA1 depicts a case where a shrinkage cavity is produced so as to extend inward from the center of a side that is far from the center line CL1. The shrinkage cavities CA2 and CA3 depict a case where shrinkage cavities are produced so as to extend inward from the centers of sides that are far from the center line CL2. The stress relieving regions 25a1 to 25a3 and 25b1 to 25b3 may be regions that include at least the shrinkage cavities CA1 to CA3. Note that the voids VO are likely to occur in the peripheries of the shrinkage cavities CA1 to CA3. As one example, the stress relieving regions 25a1 and 25b1 (or “first stress relieving regions”) may be formed in regions of the solder 25a and 25b including the center line CL2 at sides that are far from the center line CL1 of the solder 25a and 25b. Also, the stress relieving regions 25a2, 25a3, 25b2, and 25b3 may be formed in regions including respective center lines of the solder 25a and 25b (that is, lines that are parallel to the short sides 31a and 31c and pass through respective center portions of the solder 25a and 25b) at a pair of edge portions that are far from the center line CL2 of the solder 25a and 25b. In this case, the stress relieving regions 25a1 to 25a3 and 25b1 to 25b3 may have the following ranges with consideration to the locations and ranges where the shrinkage cavities CA1 to CA3 occur. That is, the stress relieving regions 25a1 to 25a3 and 25b1 to 25b3 may be regions from a side of the joining regions 36a and 36b that is far from the center line CL1 or CL2 to a position located inward by at least 5% but not greater than 30% of a length of a side perpendicular to this side and also regions that extend outward from the center of this side by at least 5% but not greater than 30% of a length of this side.

The solder 25a and 25b internally includes a number of voids. As examples, the voids referred to here are the voids VO that are surrounded by the solder 25a and 25b and the shrinkage cavities CA1 to CA3 that extend from edge portions of the joining regions 36a and 36b toward the insides of the joining regions 36a and 36b and are connected to the outsides of the joining regions 36a and 36b. Note that the formation of voids (that is, the shrinkage cavities CA1 to CA3 and the voids VO) during the manufacturing process of the semiconductor device 10 will be described later.

In the semiconductor device 10, cracking, peeling, and the like are likely to occur at outer circumferential portions of the ceramic circuit boards 21 and outer circumferential portions of the solder 25a and 25b due to differences in the coefficient of thermal expansion between the ceramic circuit board 21 and the metal base plate 30. In the present embodiments, by providing the stress relieving regions 25a1 to 25a3 and 25b1 to 25b3 in the solder 25a and 25b, it is possible to suppress the occurrence of cracks, peeling, and the like in the ceramic circuit boards 21 and the solder 25a and 25b.

On the other hand, the heat generated from the semiconductor chips 28a and 28b is transmitted from the ceramic circuit boards 21 to the solder 25a and 25b and dissipates to the outside from the metal base plate 30. When doing so, voids present in at the locations of the solder 25a and 25b that transmits the heat cause a drop in thermal conductivity (in other words, an increase in heat resistance), which reduces the dissipation of heat. In particular, since the stress relieving regions 25a1 to 25a3 and 25b1 to 25b3 included in the solder 25a and 25b have a higher density of voids than other regions, there is a large drop in thermal conductivity. For this reason, in plan view, the low-heat-dissipation regions 29a and 29b are set on the front surface of the ceramic circuit boards 21 due to these regions being positioned above the stress relieving regions 25a1 to 25a3 and 25b1 to 25b3, respectively. The semiconductor chips 28a and 28b are joined to the circuit patterns 24b and 24c on the front surface at regions of the ceramic circuit boards 21 aside from the low-heat-dissipation regions 29a and 29b. This makes it possible to suppress the drop in heat dissipation by the semiconductor device 10.

Note that in the present embodiments, although not illustrated, the semiconductor device 10 may be encapsulated in encapsulating resin. The encapsulating member used in this case contains a thermosetting resin and a filler included in the thermosetting resin. As examples, the thermosetting resin is epoxy resin, phenol resin, or maleimide resin. One example of the encapsulating member is epoxy resin containing a filler. An inorganic substance is used as the filler. As examples, the inorganic substance is silicon oxide, aluminum oxide, boron nitride, or aluminum nitride.

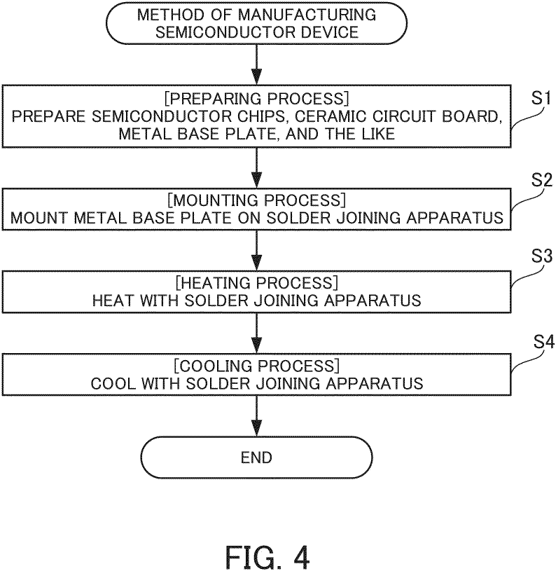

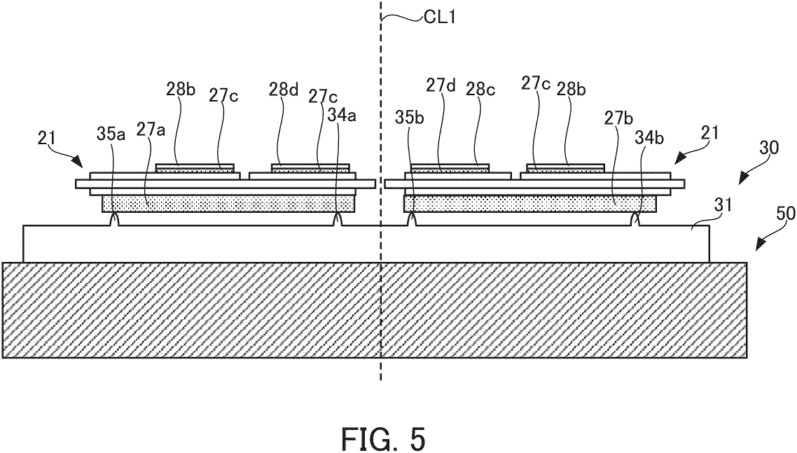

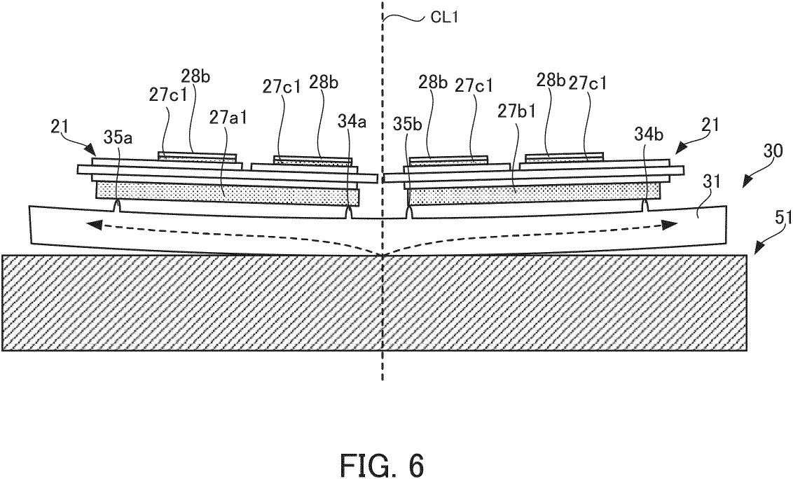

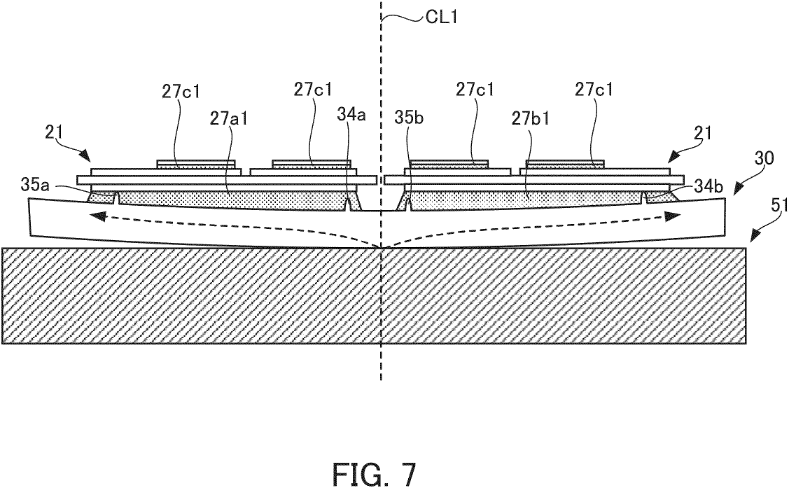

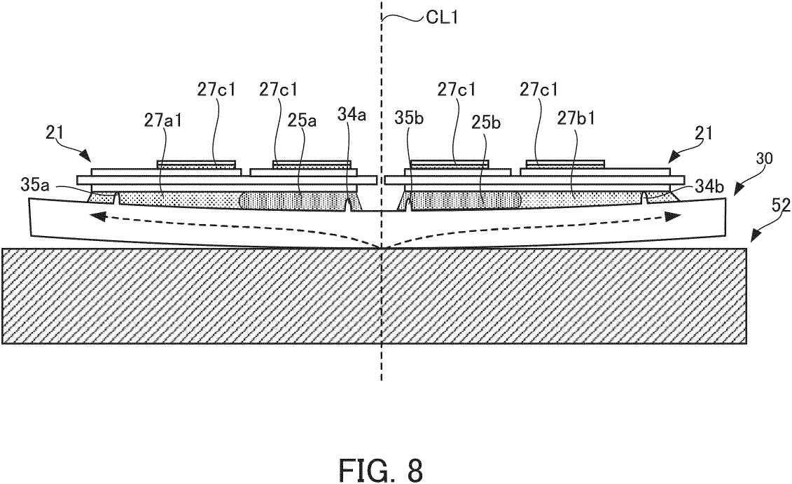

Next, a method of manufacturing the semiconductor device 10 will be described with reference to FIGS. 4 to 8. FIG. 4 is a flowchart of a method of manufacturing a semiconductor device according to the present embodiments. FIG. 5 depicts a mounting process included in the method of manufacturing a semiconductor device according to the present embodiments, FIG. 6 and FIG. 7 depict a heating process included in the method of manufacturing a semiconductor device according to the present embodiments, and FIG. 8 depicts a cooling process included in the method of manufacturing a semiconductor device according to the present embodiments. Note that FIGS. 5 to 8 are cross-sectional views at a position corresponding to the dot-dash line X-X in FIG. 1.

First, a preparing process of preparing components of the semiconductor device 10, namely the semiconductor chips 28a and 28b, the ceramic circuit boards 21, the metal base plate 30, and solder plate is performed (step S1). A solder joining apparatus, described later, and a positioning jig used in the mounting process are also prepared.

Next, the mounting process where the metal base plate 30, the solder plates 27a and 27b, the ceramic circuit boards 21, and the semiconductor chips 28a and 28b are mounted in that order on a mounting table 50 of a solder joining apparatus is performed (see FIG. 5) (step S2). Note that the semiconductor chips 28b are depicted in FIG. 5. At this time, a central portion of the metal base plate 30 through which the center line CL1 passes may be slightly warped in an upwardly convex shape. That is, the metal base plate 30 may be warped so that the central portion protrudes upward beyond the short sides 31a and 31c and the long sides 31b and 31d. The solder plates 27a and 27b are set so that their rear surfaces are supported by the protruding portions 32a to 35a and the protruding portions 32b to 35b that are formed in the joining regions 36a and 36b, respectively, of the metal base plate 30. The solder plates 27a and 27b are plate shaped and have the same composition as the solder 25a and 25b described above. The solder plates 27a and 27b have a sufficient size so that corner portions of the solder plates 27a and 27b are supported by the protruding portions 32a to 35a and the protruding portions 32b to 35b in plan view. The thicknesses of the solder plates 27a and 27b are configured to be substantially the same as or several percent higher than the heights of the protruding portions 32a to 35a and the protruding portions 32b to 35b. The ceramic circuit boards 21 are set on the solder plates 27a and 27b. The solder plates 27a and 27b are disposed on the rear surfaces of the metal plates 23 of the ceramic circuit boards 21. It is also possible to use cream solder in place of the solder plates 27a and 27b. When cream solder is used, the joining regions 36a and 36b including the protruding portions 32a to 35a and the protruding portions 32b to 35b may be coated.

Note that the solder joining apparatus is provided with a mounting table 50 on which the components are mounted, and a heating plate 51 and a cooling plate 52 which will be described later, and further includes a control device for controlling the mounting table 50, the heating plate 51, and the cooling plate 52. In the solder joining apparatus, the metal base plate 30 and the like are conveyed to the mounting table 50, the heating plate 51, and the cooling plate 52 in steps S2 to S4 respectively. The control device included in the solder joining apparatus causes the heating plate 51 to heat up and stops the heating as appropriate. The heating temperature and heating time during heating are appropriately controlled by the control device included in the solder joining apparatus. The control device included in the solder joining apparatus also causes the cooling plate 52 to cool down and stops the cooling as appropriate. The cooling temperature and cooling time during cooling are appropriately controlled by the control device included in the solder joining apparatus.

In addition, the semiconductor chips 28a and 28b are set via solder plates 27c on the circuit patterns 24b and 24c of the ceramic circuit boards 21. The semiconductor chips 28b are mounted on the circuit patterns 24b so as to avoid the low-heat-dissipation regions 29a and 29b. Note that it is assumed here that the solder plates 27c under the semiconductor chips 28a and 28b are the same type as the solder plates 27a and 27b. In step S2, a jig capable of positioning relative to the joining regions 36a and 36b of the metal base plate 30 is used. The jig is formed as a flat plate, has the same size as the metal base plate 30 in plan view, and has openings that are slightly larger than the sizes of the joining regions 36a and 36b formed in regions corresponding to the joining regions 36a and 36b. The jig is made of a material with superior heat resistance. Example materials include a composite ceramic material and carbon. The solder plates 27a and 27b, the ceramic circuit boards 21, the solder plates 27c, and the semiconductor chips 28a and 28b are set in the openings of the jig set on the metal base plate 30.

Next, the solder joining apparatus is driven to perform a heating process that heats the metal base plate 30, the solder plates 27a and 27b, the ceramic circuit boards 21, the solder plates 27c, and the semiconductor chips 28a and 28b (step S3) .

In step S3, in a state where the rear surface of the metal base plate 30 has been disposed on the heating plate 51 in the solder joining apparatus, the solder joining apparatus is driven to heat the heating plate 51, which results in the metal base plate 30, the solder plates 27a and 27b, the ceramic circuit boards 21, the solder plates 27c, and the semiconductor chips 28a and 28b being heated. The heating plate 51 has a flat upper surface and is internally provided with a heating mechanism, such as a heater, for heating up. First, the heat generated from the heating plate 51 is transmitted to the rear surface of the metal base plate 30. When this happens, since the metal base plate 30 is heated from the rear surface, the rear surface side undergoes rapid thermal expansion, so that as depicted in FIG. 6, warping occurs so that the center portion of the metal base plate 30 becomes downwardly convex. That is, the metal base plate 30 becomes warped so that the short sides 31a and 31c and the long sides 31b and 31d become positioned above the center portion. This means that the metal base plate 30 is heated by the heating plate 51 from a center portion of the rear surface of the metal base plate 30. Heat is transmitted from the center portion (the center line CL1) of the rear surface of the metal base plate 30 to outer edge portions of the metal base plate 30 (the heat dissipating plate 31) along the arrows drawn with broken lines in FIG. 6. The heat is transmitted via the heat dissipating plate 31 to the protruding portions 32a to 35a and the protruding portions 32b to 35b. After this, the solder plates 27a and 27b supported by the protruding portions 32a to 35a and the protruding portions 32b to 35b are heated and melt.

Molten solder 27a1 and 27b1 produced by the solder plates 27a and 27b melting flows toward the heat dissipating plate 31. In addition, the ceramic circuit boards 21 and the semiconductor chips 28a and 28b become pressed against the heat dissipating plate 31 by their own weight. At this time, as depicted in FIG. 7, the ceramic circuit boards 21 become substantially horizontal with respect to the heating plate 51. Accordingly, in this state, the thickness of the molten solder 27a1 and 27b1 produced by the solder plates 27a and 27b completely melting becomes thinner at edge portions away from the center line CL1 of the metal base plate 30 than the thickness at edge portions close to the center line CL1. At this time, the solder plates 27c under the semiconductor chips 28a and 28b also melt into molten solder 27c1. The molten solder 27c1 becomes pressed toward the circuit patterns 24a to 24d by the weight of the semiconductor chips 28a and 28b.

Note that the protruding portions 32a to 35a and the protruding portions 32b to 35b are rod-shaped. This means that the molten solder 27a1 and 27b1 that has melted from the solder plates 27a and 27b tends to move downward along the protruding portions 32a to 35a and the protruding portions 32b to 35b toward the joining regions 36a and 36b. The protruding portions 32a to 35a and the protruding portions 32b to 35b are rod-shaped and are provided at the corner portions of the joining regions 36a and 36b. This means that the protruding portions 32a to 35a and the protruding portions 32b to 35b are unlikely to hinder the spreading of the molten solder 27a1 and 27b1 in the joining regions 36a and 36b. At least the tip portions of the protruding portions 33a and 35a and the protruding portions 32b and 34b that are distant from the center line CL1 of the metal base plate 30 contact the rear surfaces of the semiconductor units 20a and 20b. On the other hand, all parts, including the tip portions, of the protruding portions 32a and 34a and the protruding portions 33b and 35b close to the center line CL1 are separated from the rear surface of the semiconductor units 20a and 20b. Note that the melting of the solder plates 27a and 27b into the molten solder 27a1 and 27b1 in the heating process will be described in detail later.

Next, the heating of the heating plate 51 by the solder joining apparatus is stopped, and a cooling process of cooling the molten solder 27a1 and 27b1 is performed (step S4). As depicted in FIG. 8, the cooling plate 52 is cooled in a state where the rear surface of the metal base plate 30 has been disposed on the cooling plate 52 of the solder joining apparatus. When set up in this way, the metal base plate 30, the molten solder 27a1 and 27b1, the ceramic circuit boards 21, the molten solder 27c1, and the semiconductor chips 28a and 28b are cooled. The cooling plate 52 has a flat upper surface and is internally provided with a cooling mechanism, such as water cooling pipes, that causes cooling. Note that the heating plate 51 and the cooling plate 52 may be a heating/cooling plate provided with both a heating mechanism and a cooling mechanism. Note that warping of the metal base plate 30 occurs so that the short sides 31a and 31c and the long sides 31b and 31d become positioned above the center portion. This means that the metal base plate 30 is cooled by the cooling plate 52 from the center portion of the rear surface. That is, the metal base plate 30 (the heat dissipating plate 31) is progressively cooled from the center portion (the center line CL1) toward the outer edge portions of the metal base plate 30 (the heat dissipating plate 31) along the arrows indicated with broken lines in FIG. 8. Together with this, the molten solder 27a1 and 27b1 is also cooled from the center line CL1 toward the outside. For this reason, during the cooling process, as depicted in FIG. 8, the molten solder 27a1 and 27b1 progressively solidifies from the center portion (the center line CL1) to produce a state where the solder 25a and 25b that has solidified is present at the center portion (the center line CL1) and the molten solder 27a1 and 27b1 is present at outer edge portions of the metal base plate 30. After this, due to the cooling process advancing further, the molten solder is entirely converted into the solidified solder 25a and 25b. The molten solder 27c1 is also entirely converted into the solidified solder 25c. Note that the cooling of the molten solder 27a1 and 27b1 in the cooling process will be described in detail later.

In this way, the molten solder 27a1 and 27b1 becomes the solidified solder 25a and 25b. In the same way, the molten solder 27c1 becomes the solidified solder 25c. As a result, the semiconductor chips 28a and 28b become joined to the circuit patterns 24b and 24c by the solder 25c. The semiconductor units 20a and 20b also become joined to the metal base plate 30 by the solder 25a and 25b, thereby manufacturing the semiconductor device 10. The semiconductor device 10 is removed from the cooling plate 52 of the solder joining apparatus, which results in the semiconductor device 10 depicted in FIGS. 1 and 3 being obtained.

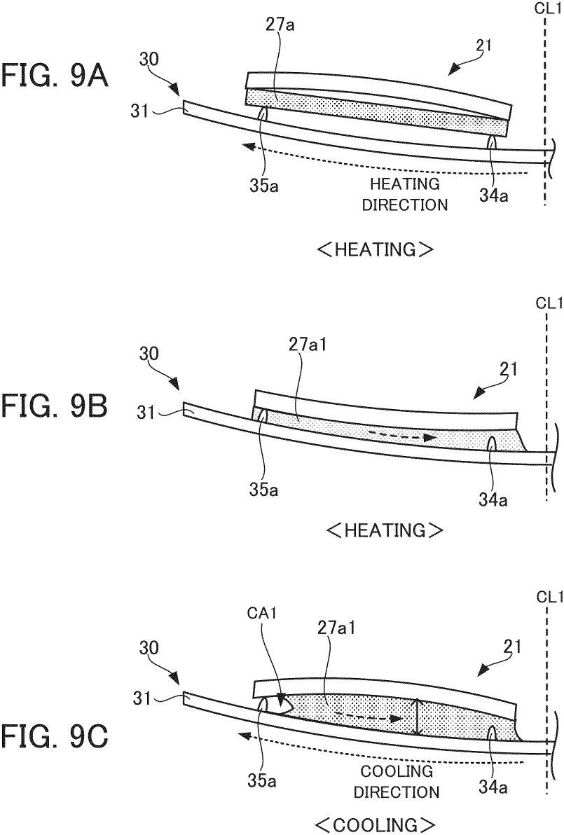

The changes in the solder plates 27a and 27b and the molten solder 27a1 and 27b2 in the heating process and the cooling process in FIGS. 4 to 8 will now be described with reference to FIGS. 9A to 9C. FIGS. 9A to 9C depict solder in the heating process and the cooling process in the method of manufacturing a semiconductor device according to the present embodiments. Note that FIGS. 9A to 9C schematically depicts the left side of the metal base plate 30, the solder plates 27a and 27b, the molten solder 27a1 and 27b1 and the ceramic circuit boards 21 depicted in FIGS. 6 to 8. Additionally, the heating process to the cooling process is depicted in chronological order. Note that detailed features of the ceramic circuit board 21 have been omitted from the drawing, and detailed features of the semiconductor chip 28a have also been omitted. In addition, the respective thicknesses have also been depicted using a different ratio to the actual thicknesses.

After the mounting process in step S2, the heating plate 51 is heated so that heating starts from the rear surface of the metal base plate 30. Note that when the front surface of the ceramic circuit board 21 is regarded as “up”, the ceramic circuit board 21 may be slightly warped so as to be upwardly convex. Also, when the metal base plate 30 is heated, as described earlier, warping occurs so that the center portion becomes downwardly convex. Heat is transmitted from the center portion (the center line CL1) of the rear surface of the metal base plate 30 toward the outer edge portions of the metal base plate 30 along the arrows indicated with broken lines in FIG. 9A. The heat is transmitted to the protruding portions 32a to 35a and the protruding portions 32b to 35b. This results in the solder plates 27a and 27b supported by the protruding portions 32a to 35a and the protruding portions 32b to 35b being heated and melting.

The molten solder 27a1 that has melted from the solder plate 27a is pressed toward the metal base plate 30 by the ceramic circuit boards 21. Also at this time, due to the ceramic circuit boards 21 being heated, warping of the ceramic circuit boards 21 occurs so that when the rear surface is regarded as “down”, the rear surface becomes downwardly convex. In this state, the molten solder 27a1 and 27b1 produced by the solder plates 27a and 27b completely melting becomes sandwiched between the ceramic circuit boards 21 and the metal base plate 30. In addition, the ceramic circuit boards 21 are heated from the rear surface side, so that thermal expansion progresses on the rear surface side and downwardly convex warping occurs. That is, downwardly convex warping occurs for both the metal base plate 30 and the ceramic circuit boards 21. This means that the metal base plate 30 and the ceramic circuit boards 21 become upwardly inclined at locations distant from the center line CL1. Accordingly, as depicted in FIG. 9B, the molten solder 27a1 flows toward the center line CL1, especially from edge portions that are distant from the center line CL1. This results in the thickness of the molten solder 27a1 at edge portions that are close to the center line CL1 becoming thicker. On the other hand, the thickness of the molten solder 27a1 at edge portions far from the center line CL1 becomes thinner. That is, the volume of the molten solder 27a1 is smaller at the edge portions far from the center line CL1 than at the edge portions close to the center line CL1.

Next, when cooling by the cooling plate 52 of the solder joining apparatus commences, the metal base plate 30 is progressively cooled from the center portion (the center line CL1) toward the outer edge portions of the metal base plate 30 along the arrows depicted using broken lines in FIG. 9C. Together with this, the molten solder 27a1 is cooled from the center line CL1 toward the outside. Accordingly, the molten solder 27a1 progressively solidifies from the center line CL1. The volume of the molten solder 27a1 shrinks as the solder changes from the molten state to the solidified state. Due to the ceramic circuit boards 21 also being cooled from the rear surface side, thermal shrinkage progresses on the rear surface side and upward convex warping of the ceramic circuit boards 21 occurs. For this reason, the molten solder 27a1 at the edge portions far from the center line CL1 is drawn toward the center line CL1. As a result, the volume of the molten solder 27a1 at edge portions far from the center line CL1 is small. Due to the protruding portion 35a on the metal base plate 30A, a predetermined distance is provided between the heat dissipating plate 31 of the metal base plate 30 and the ceramic circuit board 21 at a position far from the center line CL1 of the molten solder 27a1. Accordingly, at edge portions far from the center line CL1 of the molten solder 27a1, it is possible to form voids and shrinkage cavities (in FIG. 9C, the shrinkage cavity CA1 is depicted). As depicted in FIG. 2 and FIG. 3, the semiconductor device 10 that includes the solder 25a produced due to the molten solder 27a1 having solidified in this state is provided with first stress relieving regions 25a1 and 25b1, in which the density of voids included in the solder 25a is higher than in other regions, at edge portions far from the center line CL1 of the solder 25a.

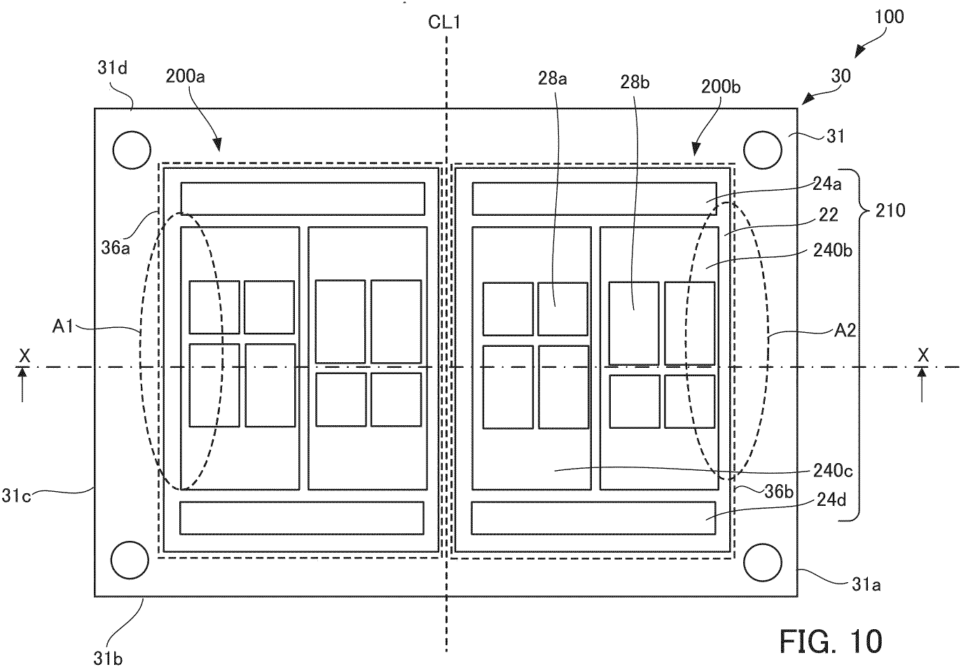

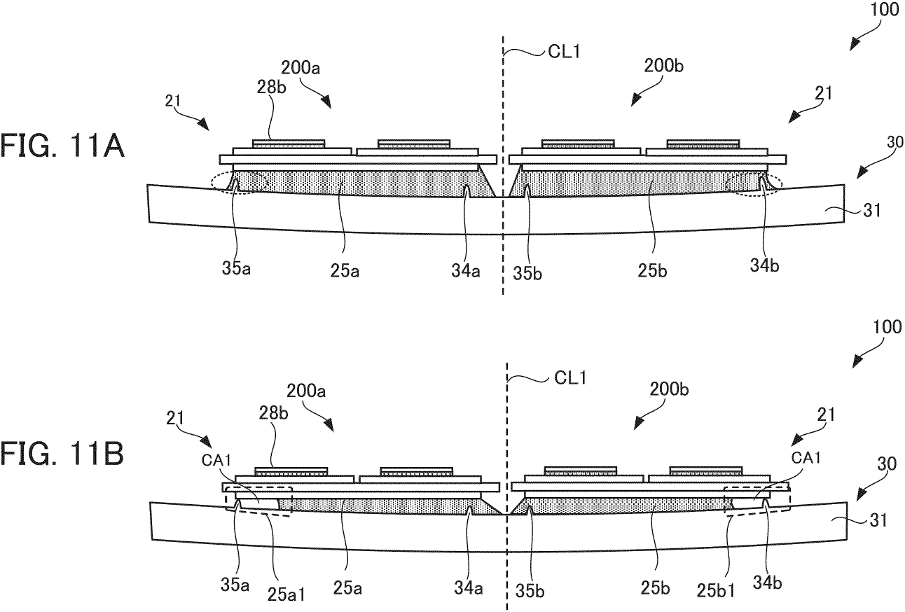

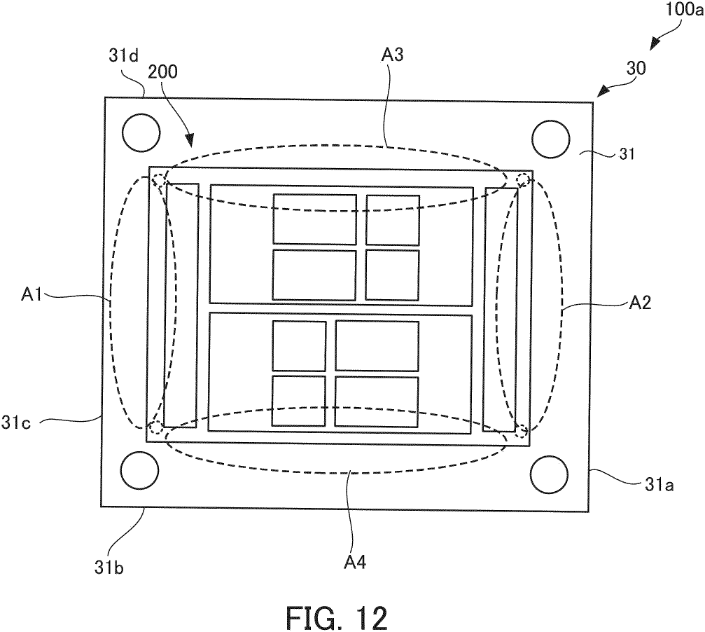

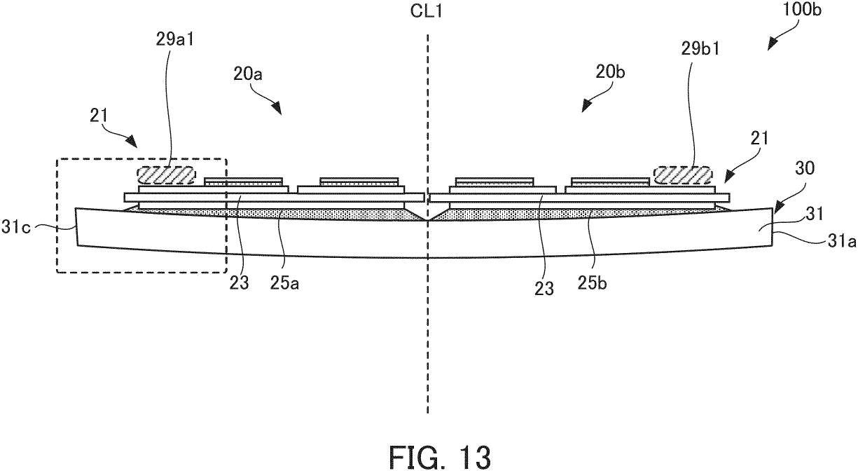

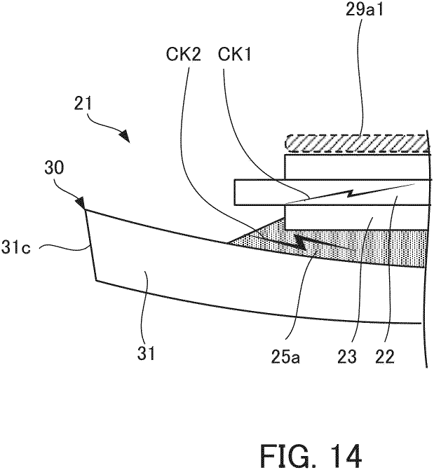

Here, semiconductor devices as comparative examples for the semiconductor device 10 will be described with reference to FIGS. 10 to 14. FIG. 10 and FIG. 12 are plan views of the semiconductor devices used as comparative examples. FIGS. 11, 13 and 14 are cross-sectional views of the semiconductor devices as comparative examples. Note that FIG. 10 depicts a case where two ceramic circuit boards 210 are disposed on the metal base plate 30, and FIG. 12 depicts a case where one ceramic circuit board 210 is disposed on the metal base plate 30. FIGS. 11A and 11B are cross-sectional views taken along a dot-dash line X-X in FIG. 10. FIG. 11A depicts a case where solder is formed with the conventional thickness, which is thicker than in the semiconductor device 10. FIG. 11B depicts a case where the solder has been formed thinner than in the case in FIG. 11A and with the same thickness as in the semiconductor device 10. FIG. 13 and FIG. 14 are cross-sectional views of a semiconductor device 100b in which the metal base plate 30 has no protruding portions. FIG. 13 corresponds to FIG. 3 for the semiconductor device 10. FIG. 14 is an enlarged view of a principal part of a region surrounded with a broken line in FIG. 13. Components of the semiconductor devices used as the comparative examples that are the same as the semiconductor device 10 have been assigned the same reference numerals and description thereof is omitted.

As depicted in FIG. 10, in the semiconductor device 100, semiconductor units 200a and 200b are joined to the metal base plate 30 by the solder 25a and 25b along the long sides 31b and 31d with line symmetry with respect to the center line CL1. Note that the thickness of the solder 25a and 25b in this configuration is made thicker than in the semiconductor device 10. The semiconductor units 200a and 200b each include a ceramic circuit board 210 and the semiconductor chips 28a and 28b that are disposed on a front surface of the ceramic circuit board 210. The semiconductor units 200a and 200b are disposed on the metal base plate 30 along the long sides 31b and 31d. Each ceramic circuit board 210 includes the ceramic board 22, the metal plate 23 formed on the rear surface of the ceramic board 22, and circuit patterns 24a, 24d, 240b, and 240c formed on the front surface of the ceramic board 22. The circuit patterns 240b and 240c differ to the semiconductor device 10 and have the same shape. The semiconductor chips 28a and 28b are joined to the circuit patterns 240b and 240c, respectively.

It is possible to manufacture the semiconductor device 100 in the same way as the flowchart depicted in FIG. 4. In the semiconductor device 100 manufactured in this manner, no shrinkage cavities were observed in the A1 region and the A2 region of the solder 25a and 25b indicated in FIG. 10. In other words, as depicted in FIG. 11A, when the thickness of the solder 25a and 25b is sufficiently thick, regions where the density of voids, such as shrinkage cavities, is higher than in other regions are not formed in the solder 25a and 25b at edge portions far from the center line CL1.

In recent years, increases in capacity and miniaturization of the semiconductor device 100 have been accompanied by increases in the density of heat generated from the semiconductor device 100. This means that it is desirable for the semiconductor device 100 to efficiently dissipate heat generated by the semiconductor chips 28a, 28b and the like. In the case of FIG. 11A where the thickness of the solder 25a and 25b is made thicker as in a conventional configuration, regions with a higher density of voids, such as shrinkage cavities, than in other regions are not formed. However, since the solder 25a and 25b is thick, an increase in thermal resistance also needs to be considered. This means that there is the risk of the semiconductor device 100 overheating and breaking due to the heat generated by the semiconductor chips 28a, 28b, and the like.

It is desirable to make the solder 25a and 25b thinner to help improve heat dissipation by the semiconductor device 100. Even when sufficiently thin solder 25a and 25b is formed in the same way as in the semiconductor device 10, it is possible to perform manufacturing in the same way as in the flowchart depicted in FIG. 4. A semiconductor device 100 manufactured with the solder 25a and 25b made thinner in this way has improved heat dissipation. However, as was described using FIGS. 9A to 9C, when the thickness of the solder 25a and 25b was reduced, as depicted in FIG. 11B, regions (that is, the “stress relieving regions 25a1 and 25b1”) where the density of voids, such as the shrinkage cavities CA1 which occur from edge portions far from the center line CL1 of the solder 25a and 25b, is higher than in other regions were formed. When the stress relieving regions 25a1 and 25b1 are located below the semiconductor chips 28a and 28b, this will increase the thermal resistance at the semiconductor chips 28a and 28b.

Also, in the semiconductor device 100 depicted in FIG. 10, the semiconductor units 200a and 200b are disposed on the metal base plate 30 along the long sides 31b and 31d with line symmetry with respect to the center line CL1. The semiconductor chips 28a and 28b are also disposed in the A1 and A2 regions depicted in FIG. 10. In the semiconductor device 100, the stress relieving regions 25a1 and 25b1 are formed in the regions A1 and A2 depicted in FIG. 10 of the solder 25a and 25b. This means that the semiconductor chips 28a and 28b are disposed in low-heat-dissipation regions on the front surface of the ceramic circuit boards 21 that are positioned above the stress relieving regions 25a1 and 25b1. Accordingly, there is a drop in the heat dissipation by the semiconductor chips 28a and 28b, resulting in the risk of the semiconductor device 100 overheating and breaking.

As another example, in a semiconductor device 100a depicted in FIG. 12, one semiconductor unit 200 is disposed via solder (not illustrated) in a center portion of the metal base plate 30. Note that the semiconductor unit 200 has the same configuration as the semiconductor units 200a and 200b. Here also, regions (or “stress relieving regions”) where the density of voids, such as shrinkage cavities, is higher than in other regions are formed in regions A3 and A4, in addition to the regions A1 and A2, depicted in FIG. 12 in the solder on the rear surface of the semiconductor unit 200. That is, when one semiconductor unit 200 is disposed in the center portion of the metal base plate 30, stress relieving regions are formed in edge portions (or “outer circumferential portions”) of the solder on the long sides 31b and 31d in addition to the short sides 31a and 31c of the metal base plate 30. The semiconductor chips 28a and 28b are also disposed in the regions A3 and A4 depicted in FIG. 12. This means that the semiconductor chips 28a and 28b are disposed in low-heat-dissipation regions on the front surface of the ceramic circuit board 21 that are positioned above the stress relieving regions. Accordingly, there is a drop in heat dissipation by the semiconductor chips 28a and 28b, resulting in the risk of the semiconductor device 100a overheating and breaking.

As another example, a semiconductor device 100b depicted in FIGS. 13 and 14 will now be described. In the semiconductor device 100b, like the semiconductor device 10, the solder is formed sufficiently thinly, but unlike the semiconductor device 10, the metal base plate 30 has no protruding portions. The semiconductor device 100b of this configuration may also be manufactured in the same way as the flowchart depicted in FIG. 4.

The semiconductor device 100b manufactured in this way by making the solder 25a and 25b thinner has improved heat dissipation. However, stress relieving regions are not formed at the edge portions (outer peripheral portions) of the solder 25a and 25b. This means that due to the difference in the coefficients of thermal expansion between the ceramic circuit boards 21 and the heat dissipating plate 31, as the temperature changes, stress is generated at outer peripheral portions of the ceramic circuit boards 210 and the outer peripheral portions of the solder 25a and 25b. The solder thickness is especially thin at edge portions far from the center line CL1. This means that as depicted in FIG. 14, there is the risk of this stress causing damage to the ceramic board 22 and the solder 25a and 25b due to cracks CK1 and CK2, peeling, and the like.

For this reason, the semiconductor device 10 described above is provided with the semiconductor chips 28a and 28b, the metal base plate 30, and the ceramic circuit boards 21 that are joined to the metal base plate 30 by the solder 25a and 25b. The metal base plate 30 is rectangular in plan view, has joining regions 36a and 36b set on the front surface, and has the center line CL1 that is parallel to the pair of short sides 31a and 31c that face each other and is located in the middle between the pair of short sides 31a and 31c. Each ceramic circuit board 21 includes the ceramic board 22 that is rectangular in plan view, the circuit pattern 24b that is formed on the front surface of the ceramic board 22 and onto which the semiconductor chips 28a and 28b are joined, and the metal plate 23 that is formed on the rear surface of the ceramic board 22 and which is joined to a joining region 36a or 36b by the solder 25a or 25b. Here, the solder 25a and 25b is provided with the stress relieving regions 25a1 and 25b1, where the density of voids included in the solder 25a and 25b is higher than in the other regions, at edge portions that are far from the center line CL1. In this semiconductor device 10, each ceramic circuit board 21 is provided with the low-heat-dissipation regions 29a and 29b that are positioned above the stress relieving regions 25a1 and 25b1 in plan view. This means that in the semiconductor device 10, it is possible to join the semiconductor chips 28a and 28b to the ceramic circuit board 21 while avoiding the low-heat-dissipation regions 29a and 29b. Accordingly, with the semiconductor device 10, it is possible to reduce the thickness of the solder 25a and 25b while suppressing breakage of the ceramic circuit board 21 and the solder 25a and 25b, which makes miniaturization and stable operation at high temperature possible.

For the semiconductor device described above, modifications to the stress relieving regions in the solder for various layout patterns of the semiconductor units 20 disposed on the metal base plate 30 and low-heat-dissipation regions corresponding to these stress relieving regions will now be described with reference to FIGS. 1 to 8. Note that in the modifications described below, components not worthy of description have not been given reference numerals and are omitted from the description.

### First Modification

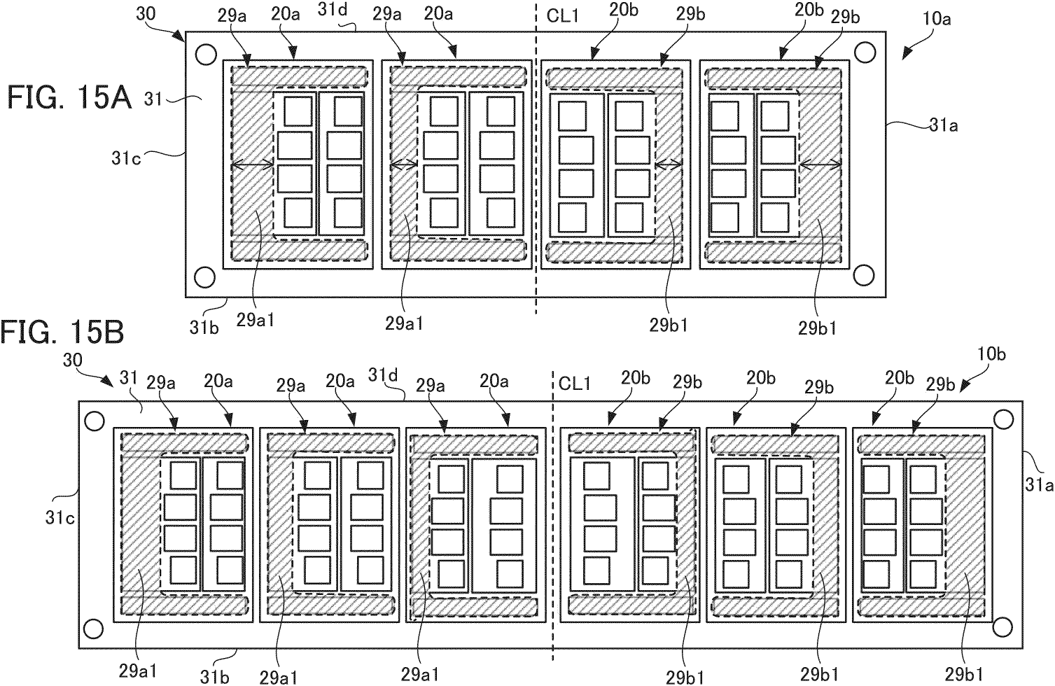

A semiconductor device according to a first modification will now be described with reference to FIGS. 15A and 15B. FIGS. 15A and 15B are plan views of the semiconductor device according to the first modification to the present embodiments. In the first modification, in the semiconductor device 10 depicted in FIG. 1, the plurality of semiconductor units 20a and 20b are disposed via the solder 25a and 25b (not illustrated) along the long sides 31b and 31d of the metal base plate 30 with line symmetry with respect to the center line CL1. As one example, the semiconductor device 10a depicted in FIG. 15A has pairs of the semiconductor units 20a and 20b, that is, a total of four semiconductor units 20a and 20b, disposed on the metal base plate 30 with line symmetry with respect to the center line CL1. The semiconductor device 10b depicted in FIG. 15B has sets of three of the semiconductor units 20a and 20b, that is, a total of six semiconductor units 20a and 20b, disposed on the metal base plate 30 with line symmetry with respect to the center line CL1.

When a plurality of semiconductor units 20a and 20b are disposed via solder 25a and 25b along the long sides 31b and 31d of the metal base plate 30 in this way with line-symmetry with respect to the center line CL1, the solder of the semiconductor units 20a and 20b includes the stress relieving regions 25a1 to 25a3 and 25b1 to 25b3 in the same way as in FIGS. 1 to 3. Due to this, low-heat-dissipation regions 29a and 29b are set on the front surfaces of the semiconductor units 20a and 20b. However, when a plurality of semiconductor units 20a and 20b are disposed with line symmetry with respect to the center line CL1 along the long sides 31b and 31d of the metal base plate 30, the widths of the stress relieving regions 25a1 and 25b1 (along the length direction of the metal base plate 30) increases as the distance from the semiconductor units 20a and 20b to the center line CL1 increases. Together with this, the widths of the short side parts 29a1 and 29b1 included in the low-heat-dissipation regions 29a and 29b also increase.

During the manufacturing of the semiconductor devices 10a and 10b, as described with reference to FIGS. 9A to 9C, the ceramic circuit boards 21 are joined to the metal base plate 30 by the solder 25a and 25b. During this process, the metal base plate 30 becomes warped downward. This means that the inclination of the metal base plate 30 increases as the distance from the center line CL1 of the metal base plate 30 increases. That is, the longer the distance from the center line CL1 of the metal base plate 30, the greater the flow of the molten solder 27a1 and 27b1 toward the center line CL1. Accordingly, the volume of the molten solder 27a1 and 27b1 at edge portions far from the center line CL1 decreases as the distance from the center line CL1 increases.

Also, to solidify the molten solder 27a1 and 27b1, the molten solder 27a1 and 27b1 are cooled from the center portion of the rear surface of the metal base plate 30 which is warped so as to be downwardly convex. Accordingly, the cooling is delayed as the distance from the center line CL1 of the metal base plate 30 increases. That is, the volume of the molten solder 27a1 and 27b1 shrinks more slowly as the distance from the center line CL1 of the metal base plate 30 increases. This means that for the molten solder 27a1 and 27b1 that is distant from the center line CL1, the volume at edge portions far from the center line CL1 is small and shrinkage in the volume also slows. Also, as described earlier, due to the protruding portion 35a of the metal base plate 30, a predetermined gap is provided between the heat dissipating plate 31 of the metal base plate 30 and the ceramic circuit board 21 at positions far from the center line CL1 of the molten solder 27a1. This means the further the molten solder 27a1 and 27b1 is from the center line CL1, the longer the shrinkage cavities produced in edge portions that are far from the center line CL1.

For this reason, when a plurality of semiconductor units 20a and 20b are disposed via the solder 25a and 25b with line symmetry with respect to the center line CL1 along the long sides 31b and 31d of the metal base plate 30, the widths (along the length direction of the metal base plate 30) of the stress relieving regions 25a1 and 25b1 in the solder 25a and 25b increases as the distance from the center line CL1 increases. Accordingly, the widths of the short side parts 29a1 and 29b1 of the low-heat-dissipation regions 29a and 29b also increases.

### Second Modification

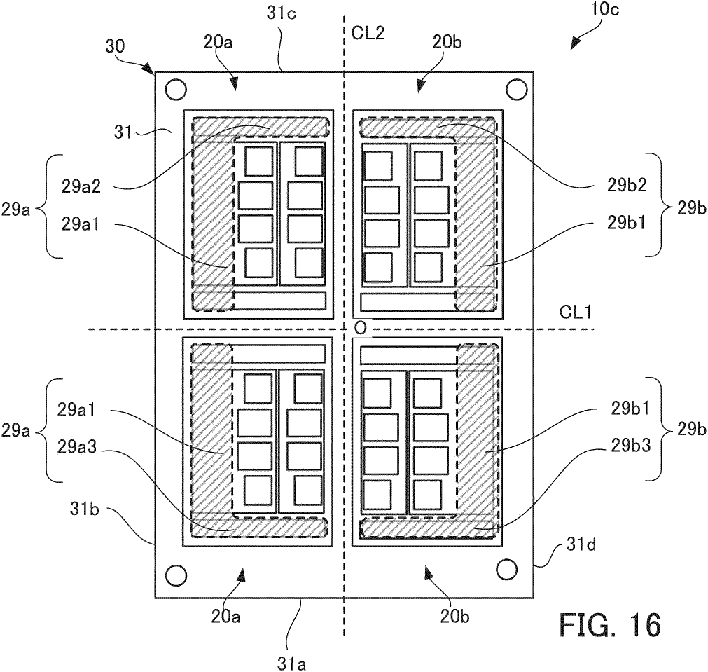

A semiconductor device 10c according to a second modification will now be described with reference to FIG. 16. FIG. 16 is a plan view of the semiconductor device according to the second modification to the present embodiments. In the second modification, a configuration where the semiconductor device 10 depicted in FIG. 1 has the semiconductor units 20 disposed with line symmetry with respect to the center lines CL1 and CL2 will be described. As one example, the semiconductor device 10c depicted in FIG. 16 is configured so that the semiconductor units 20a and 20b are joined by the solder 25a and 25b to the metal base plate 30 in two rows and two columns so as to have line symmetry with respect to the center lines CL1 and CL2.

When manufacturing the semiconductor device 10c, on the metal base plate 30 which has the semiconductor units 20a and 20b disposed in two rows and two columns and which is warped so as to be downwardly convex, for the reasons described earlier, voids such as shrinkage cavities and cracks are produced in the solder 25a and 25 at positions that are distant from a center point 0 where the center lines CL1 and CL2 intersect. For this reason, the short side parts 29a1 and 29b1 and long side parts 29a2 and 29b2 of the low-heat-dissipation regions 29a and 29b corresponding to the stress relieving regions (not illustrated) at edge portions that are far from the center point 0 are set for the semiconductor units 20a and 20b in the first row. Short side parts 29a1 and 29b1 and long side parts 29a3 and 29b3 of the low-heat-dissipation regions 29a and 29b corresponding to the stress relieving regions (not illustrated) at edge portions that are far from the center point 0 are set for the semiconductor units 20a and 20b in the second row.

### Third and Fourth Modifications

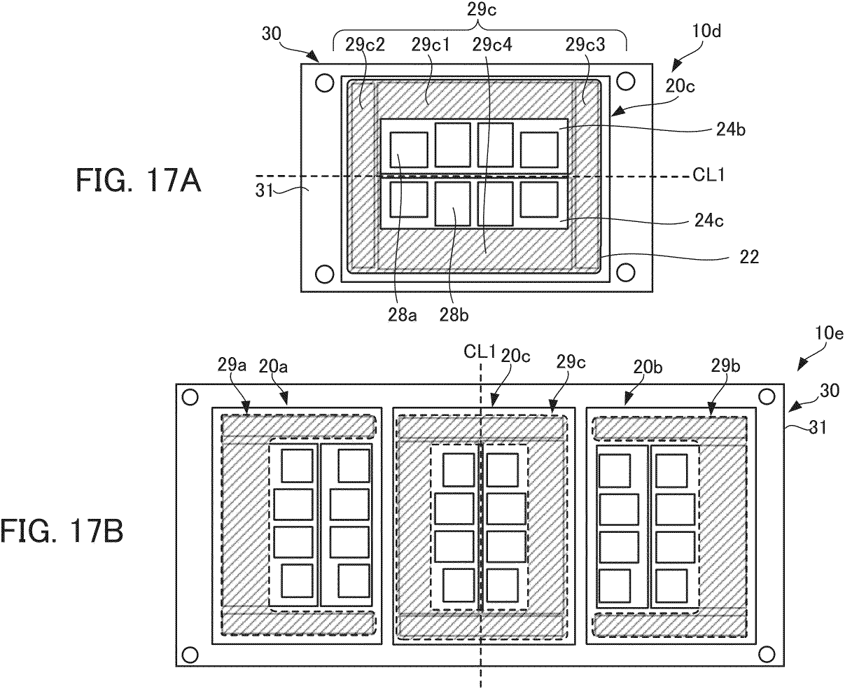

Semiconductor devices 10d and 10e according to third and fourth modifications will now be described with reference to FIGS. 17A and 17B. FIGS. 17A and 17B are plan views of the semiconductor devices according to the third and fourth modifications. Note that FIG. 17A depicts the semiconductor device 10d according to the third modification and FIG. 17B depicts the semiconductor device 10e according to the fourth modification.

In the third modification, a case is described where one semiconductor unit is disposed so as to be centered on the center line CL1 on the metal base plate 30 (corresponding to the comparative example depicted in FIG. 12). The semiconductor device 10d depicted in FIG. 17A has the metal base plate 30 and a semiconductor unit 20c joined via solder (not illustrated) onto the metal base plate 30.

As was described with reference to FIG. 12, in the solder in the semiconductor device 10d, the occurrence of voids such as shrinkage cavities and cracks was observed not only at a pair of edge portions on both sides of the center line CL1 but also in a pair of edge portions that are perpendicular to these edge portions. For this reason, an (O-shaped) low-heat-dissipation region 29c corresponding to a stress relieving region (not illustrated) around an outer peripheral portion of the semiconductor unit 20c is set for the semiconductor unit 20c. The low-heat-dissipation region 29c includes short side parts 29c1 and 29c4 and long side parts 29c2 and 29c3 set in an outer peripheral portion of the semiconductor unit 20c.

For this reason, the circuit patterns 24b and 24c of the ceramic circuit board 21 included in the semiconductor unit 20c include regions (non-mounting regions) that have the same shape and extend up to the edge portions of the ceramic board 22 (the sides facing the long sides of the metal base plate 30) and are positioned above the short side parts 29c1 and 29c4 of the low-heat-dissipation region 29c. The semiconductor chips 28a and 28b are joined to the front surfaces of the circuit patterns 24b and 24c at positions aside from the short side parts 29c1 and 29c4 of the low-heat-dissipation region 29c.

In the fourth modification, a case is described where the semiconductor unit 20c of the third modification is disposed in a center portion of the metal base plate 30 and the semiconductor units 20a and 20b are disposed via the solder 25a and 25b (not illustrated) on the metal base plate 30 so as to have line symmetry with respect to the center line CL1 on both sides of the semiconductor unit 20c.

A semiconductor device 10e depicted in FIG. 17B includes the metal base plate 30, the semiconductor unit 20c disposed so as to be centered on the center line CL1 of the metal base plate 30, and the semiconductor units 20a and 20b disposed via the solder 25a and 25b in adjacent joining regions located on both sides of the semiconductor unit 20c with line symmetry with respect to the center line CL1. In this semiconductor device 10e, the semiconductor unit 20c is disposed so as to be centered on the center line CL1 of the metal base plate 30. Accordingly, in the same way as the third modification, voids such as shrinkage cavities and cracks were observed note only at a pair of edge portions on both sides of the center line CL1 but also at a pair of edge portions that are perpendicular to these edge portions. For this reason, an (O-shaped) low-heat-dissipation region 29c corresponding to a stress relieving region (not illustrated) around an outer peripheral portion of the semiconductor unit 20c is set for the semiconductor unit 20c.

For the ceramic circuit boards 21 of the semiconductor units 20a and 20b, in the same way as the first modification, low-heat-dissipation regions 29a and 29b corresponding to stress relieving regions (not illustrated) are set at the edge portions of the solder 25a and 25b that are far from the center line CL1.

### Fifth Modification

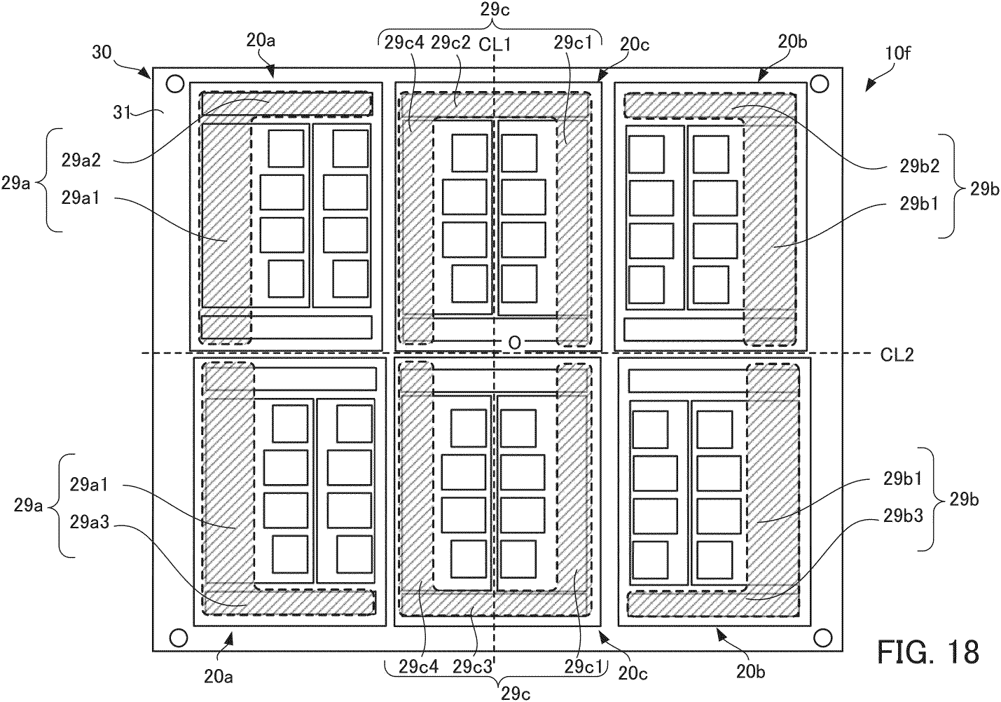

A semiconductor device according to a fifth modification will now be described with reference to FIG. 18. FIG. 18 is a plan view of a semiconductor device according to the fifth modification to the present embodiments. In this fifth modification, a case where the semiconductor units 20a, 20c, and 20b of the fourth modification are disposed in two rows will be described. The semiconductor device 10f depicted in FIG. 18 includes the metal base plate 30 and the semiconductor units 20a, 20c, and 20b, which have been disposed via solder in two rows on the metal base plate 30.

In the semiconductor device 10f, in the same way as the second modification, first, on a metal base plate 30 on which the semiconductor units 20a, 20c, and 20b are disposed in two rows and three columns, voids, such as shrinkage cavities and cracks, were observed in the solder at positions that are distant from the center point 0 where the center lines CL1 and CL2 intersect. For this reason, in the semiconductor units 20a, 20c, and 20b in the first row, the low-heat-dissipation regions 29a, 29c, and 29b (the short side parts 29a1 and 29b1 and the long side parts 29a2, 29c2, and 29b2) are set corresponding to the stress relieving regions (not illustrated) at the edge portions that are far from the center point O. In the semiconductor units 20a, 20c, and 20b in the second row, the low-heat-dissipation regions 29a, 29c, and 29b (the short side parts 29a1 and 29b1 and the long side parts 29a3, 29c3, and 29b3) are set corresponding to the stress relieving regions (not illustrated) at the edge portions that are far from the center point O.

In addition, as described in the fourth modification, the solder of the semiconductor units 20c disposed so as to be centered on the center line CL1 of the metal base plate 30 includes stress relieving regions (not illustrated) at a pair of edge portions on both sides of the center line CL1. Accordingly, on the ceramic circuit boards 21 of the semiconductor units 20c, the short side parts 29c1 and 29c4 of the low-heat-dissipation regions 29c are set corresponding to these stress relieving regions.

The semiconductor devices 10a to 10f of the first to fifth modifications described above join the semiconductor chips 28a and 28b to the ceramic circuit boards 21 so as to avoid the low-heat-dissipation regions 29a, 29b, and 29c, and make it possible to reduce the thickness of the solder while suppressing breakage of the ceramic circuit board 21 and the solder 25a and 25b, which makes miniaturization and stable operation at high temperature possible.

According to the present disclosure, it is possible to suppress damage to a ceramic circuit board and solder while improving heat dissipation by reducing the thickness of solder, which makes it possible to increase the capacity of a semiconductor device and to improve the reliability.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor device, comprising:
a first semiconductor chip;
a metal base plate which is rectangular in a plan view of the semiconductor device, has a joining region disposed on a front surface thereof, and has a first center line that is parallel to a pair of first sides which face each other and in a middle so as to be interposed between the pair of first sides;
a first joining member; and
a first insulated circuit board including a first insulated board that is rectangular in the plan view, a first circuit pattern that is formed on a front surface of the first insulated board and has the first semiconductor chip joined thereto, and a first metal plate that is formed on a rear surface of the first insulated board and joined to the joining region by the first joining member, wherein
the first joining member:
joins the metal base plate and the first metal plate, and
has a fillet formed so as to flare outwardly from an outer peripheral end portion of the first metal plate, and
part of a first edge portion of the first joining member, which is located away from the first center line, is provided with a first stress relieving region, the first joining member having plural regions including the first stress relieving region, that contain voids, a density of the voids contained in the first stress relieving region being higher than densities of the voids contained in others of the plural regions of the first joining member.

2. The semiconductor device according to claim 1, wherein in the plan view, the first semiconductor chip is joined to the first circuit pattern on the front surface in a region that is not a region positioned above the first stress relieving region.

3. The semiconductor device according to claim 1, wherein
in the plan view, the first circuit pattern includes a non-overlapping region and an overlapping region that is positioned above the first stress relieving region and extends to the first edge portion, the non-overlapping region being a region of the first circuit pattern other than the overlapping region, and
the first semiconductor chip is joined to the non-overlapping region and is not joined to the overlapping region.

4. The semiconductor device according to claim 1, wherein in the plan view, the first insulated circuit board further includes another circuit pattern formed in a region of the first insulated board that is positioned above the first stress relieving region.

5. The semiconductor device according to claim 1, wherein
the metal base plate has a second center line that is perpendicular to the pair of first sides, parallel to a pair of second sides that face each other, and interposed in a middle between the pair of second sides, and
the plural regions of the first joining member that contain voids further include a second stress relieving region at a second edge portion that is away from the second center line, a density of the voids contained in the second stress relieving region being higher than densities of the voids contained in others of the plural regions aside from the first stress relieving region.

6. The semiconductor device according to claim 5, wherein
the first insulated circuit board is also disposed on the metal base plate so as to be centered on the second center line, and
the second stress relieving region is disposed at an other second edge portion that face the second edge portion, the second edge portion and the other second edge portion being parallel to the pair of second sides.

7. The semiconductor device according to claim 5, wherein the voids contained in at least one of the first stress relieving region or the second stress relieving region include a void that extends inwardly from the first edge portion or the second edge portion of the first joining member.

8. The semiconductor device according to claim 1, wherein a thickness of the first joining member is less at the first edge portion than at a portion above the first center line.

9. The semiconductor device according to claim 1, wherein
at least one of the metal base plate or the first insulated circuit board is warped,
for warpage of the metal base plate, the metal base plate is warped with a rear surface of the metal base plate down, so as to be downwardly convex centered on the first center line, and
for warpage of the first insulated circuit board, the first insulated circuit board is warped with the front surface of the first insulated circuit board being up, so as to be upwardly convex centered on a position above the first center line.

10. The semiconductor device according to claim 1, wherein
the metal base plate has a plurality of the joining regions, which are formed in a plurality of columns, and which have line symmetry about the first center line and are aligned along a pair of facing second sides that are perpendicular to the pair of first sides,
the first insulated circuit board is provided in plurality, the plurality of insulated circuit boards being respectively joined to the joining regions in the plurality of columns by the first joining member and including two adjacent first insulated circuit boards along the second sides, and
for the two adjacent first insulated circuit boards, a width in a direction parallel to the second sides of the first stress relieving region in one of the adjacent first insulated circuit boards is wider than a width of the first stress relieving region in the other one of the adjacent first insulated circuit boards, which is closer to the first center line than the one of the adjacent first insulated circuit boards.

11. The semiconductor device according to claim 10, wherein the first stress relieving region of the first joining member is not disposed at an edge portion that is adjacent to the first center line.

12. The semiconductor device according to claim 10, wherein
the metal base plate has a second center line that is parallel to the pair of second sides and is interposed in a middle between the pair of second sides, and the plurality of joining regions in the columns are positioned in a plurality of rows along the pair of first sides and have line symmetry across the second center line,
the first insulated circuit boards are respectively joined by the first joining member to the joining regions in the plurality of rows, and
the first joining member includes the plural regions, including a second stress relieving region at a second edge portion that is away from the second center line, that contain voids, a density of the voids contained in the second stress relieving region being higher than densities of the voids contained in others of the plural regions of the first joining member aside from the first stress relieving region.

13. The semiconductor device according to claim 1, wherein
the joining region of the metal base plate is provided in a center of the metal base plate as a first joining region, and the metal base plate further has a pair of second joining regions that are arranged adjacent to respective ones of both sides of the first joining region so as to have line symmetry about the first center line, and
the first stress relieving region of the first joining member is provided at an entire peripheral edge portion thereof including the first edge portion,
the semiconductor device further comprising:
a pair of second semiconductor chips;
a pair of second joining members;
a pair of second insulated circuit boards each including
a second insulated board that is rectangular in the plan view,
a second circuit pattern that is formed on a front surface of the second insulated board and has a respective one of the second semiconductor chips joined thereto, and
a second metal plate that is formed on a rear surface of the second insulated board and joined to a respective one of the second joining regions via a respective one of the second joining members, wherein each of the second joining members:
joins the metal base plate and the second metal plate, and
has a fillet formed so as to flare outwardly from an outer peripheral end portion of the second metal plate, each of the second joining members having plural regions, including a second stress relieving region at a first edge portion that is away from the first center line and at a pair of second edge portions, containing voids, a density of the voids contained in the second stress relieving region being higher than densities of voids contained in others of the plural regions of the second joining member.

14. The semiconductor device according to claim 1, wherein
the first insulated circuit board and the first joining member each are provided in a plurality of two,
the joining region of the metal base plate includes a pair of row joining regions, each of which includes one of the first joining region at a center of the metal base plate and a pair of second joining regions that are arranged adjacent to respective ones of both sides of the one of the first joining regions so as to have line symmetry about the first center line, and
the first metal plates of respective ones of the first insulated circuit boards are joined to respective ones of the first joining regions of the row joining regions by respective ones of the first joining members,
each first joining member further includes an other first edge portion and a second edge portion, and the first stress relieving region of each first joining member is provided at the first edge portion, the other first edge portion, and the second edge portion that is away from a second center line that is parallel to a pair of second sides that are perpendicular to the pair of first sides and is interposed in a middle between the pair of second sides, the semiconductor device further comprising:
a plurality of second semiconductor chips;
a plurality of second joining members;
a plurality of second insulated circuit boards each including
a second insulated board that is rectangular in the plan view,
a second circuit pattern that is formed on a front surface of the second insulated board and has one of the second semiconductor chips joined thereto, and
a second metal plate that is formed on a rear surface of the second insulated board and joined to a respective one of the second joining regions via a respective one of the second joining members, wherein each of the second joining members:
joins the metal base plate and the second metal plate, and
has a fillet formed so as to flare outwardly from an outer peripheral end portion of the second metal plate, each of the second joining members having plural regions, including a second stress relieving region at a first edge portion that is away from the first center line and at a second edge portion that is away from the second center line, that contain voids, a density of the voids contained in the second stress relieving region being higher than densities of the voids contained in others of the plural regions of the second joining member.

15. The semiconductor device according to claim 1, wherein the first joining member is solder.

16. The semiconductor device according to claim 1, wherein the metal base plate further includes protruding portions, which are integrally formed therewith, and are respectively formed at corner portions of the joining region of the metal base plate.

17. A method of manufacturing a semiconductor device, comprising:
a preparing process of preparing a metal base plate, which is rectangular in a plan view of the semiconductor device, has a joining region on a front surface thereof, and has a first center line that is parallel to and disposed between a pair of first sides which face each other, a semiconductor chip, and an insulated circuit board, which includes an insulated board that is rectangular in the plan view, a circuit pattern that is formed on a front surface of the insulated board, and a metal plate that is formed on a rear surface of the insulated board,
a mounting process of mounting the insulated circuit board via a joining plate member onto the joining region of the metal base plate and mounting the semiconductor chip onto the circuit pattern on the front surface thereof so as to avoid a region which is along one edge portion of the insulated circuit board that is away from the first center line within a specified range from the one edge portion;
a heating process of heating the metal base plate, the joining plate member, the insulated circuit board, and the semiconductor chip to melt the joining plate member into a molten joining member; and
a cooling process of cooling the metal base plate, the molten joining member, the insulated circuit board, and the semiconductor chip to join the insulated circuit board to the metal base plate with a joining member produced by solidification of the molten joining member, wherein the joining member joins the metal base plate and the metal plate, has a fillet formed so as to flare outwardly from an outer peripheral end portion of the metal plate, and wherein a stress relieving region, where a density of voids included in the joining member is higher than a density of voids in other regions of the joining member, is produced at a part of a region of the joining member that is positioned above the region of the specified range in the plan view.

18. The method of manufacturing a semiconductor device according to claim 17, wherein, designating a rear surface of a metal base plate prepared in the preparing process as a bottom side of the metal base plate, a center portion of the rear surface is warped so as to be downwardly convex, and
when the joining plate member melts in the heating process, positions on the metal base plate are located increasingly higher as a distance from the center portion increases.

19. The method of manufacturing a semiconductor device according to claim 18, wherein in the cooling process, after the heating process, the metal base plate, on which the insulated circuit board and the semiconductor chip have been laminated, is placed on a flat cooling plate and the metal base plate is cooled from the center portion thereof.
